(19) United States
(12) Patent Application Publication
(10) Pub. No.: US 2018/0138287 A1
(43) Pub. Date: May 17, 2018

(54) METHOD OF MANUFACTURING SILICON CARBIDE SEMICONDUCTOR DEVICE

(71) Applicant: Fuji Electric Co., Ltd., Kanagawa (JP)

(72) Inventor: Takashi TSUJI, Nagano (JP)

(73) Assignee: Fuji Electric Co., Ltd., Kanagawa (JP)

(21) Appl. No.: 15/724,181

(22) Filed: Oct. 3, 2017

(30) Foreign Application Priority Data
Nov. 15, 2016 (JP) 2016-222772

(51) Int. Cl. H01L 29/66; H01L 29/78; H01L 21/263

(52) U.S. Cl. CPC H01L 29/66068; H01L 21/2636; H01L 29/7813

(57) ABSTRACT

In a method of manufacturing a silicon carbide semiconductor device, an n-type drift layer and a p-type epitaxial base layer are sequentially deposited onto an n-type silicon carbide substrate. Next, n-type source regions and a p-type base contact region are formed in the surface layer of the p-type epitaxial base layer. Then, laser annealing is performed by irradiating the surface layer of the n-type source regions and the surface layer of the p-type base contact region with a laser.

### BACKGROUND OF THE INVENTION

### Technical Field

The present invention relates to a method of manufacturing a silicon carbide semiconductor device using silicon carbide (SiC) as the semiconductor material.

### Background Art

In vertical power devices that use a silicon carbide semiconductor, the dielectric breakdown field strength at which avalanche breakdown occurs is approximately 10 times greater than in silicon (Si) semiconductor vertical power devices. This makes it possible to make the ON-resistance per unit area R_{on, sp} given by the following equation several hundredths that of silicon vertical power devices. Here, E_{C} is dielectric breakdown field strength, μ is electron mobility, ε_{SiC} is the permittivity of silicon carbide, and BV is the breakdown voltage of the device.

R_{on,sp}=4BV²/ε_{SiC}μE_{C}³

Therefore, using silicon carbide power devices in power electronic circuits such as inverter circuits makes it possible to reduce system loss by several dozen percent relative to when using silicon power devices. For this reason, silicon carbide power devices are being used in an increasingly wide range of applications in industry.

Among silicon carbide vertical power devices, metal-oxide-semiconductor field-effect transistors (MOSFETs) are used particularly widely due to the ability for the gate to be voltage-driven and the low power consumption of the associated gate drivers, for example. The ON-resistance of a MOSFET is equal to the sum of the source metal contact resistance, source resistance, MOS channel resistance, JFET resistance, drift resistance, substrate resistance, and rear surface drain contact resistance. In relatively low withstand voltage classes such as the 600V or 1200V class, the MOS channel resistance accounts for the largest percentage of the overall ON-resistance among these components. Moreover, one extremely effective way to reduce MOS channel resistance is to reduce the cell pitch.

However, in so-called planar MOSFET structures in which the MOS channel is formed parallel to the principal surface, JFET resistance arises in the upper portion of the drift layer sandwiched between the base layers of adjacent cells. Here, reducing the cell pitch increases this JFET resistance. Therefore, in planar MOSFETs, ON-resistance cannot be sufficiently reduced even if the cell pitch is reduced.

Trench MOSFETs in which the gate electrode is formed inside a trench have been proposed as one solution to this problem. FIG. 4 is a cross-sectional view illustrating the structure of a conventional trench MOSFET. As illustrated in FIG. 4, this trench MOSFET includes trenches 107 formed in the principal surface, gate oxide films 108 formed on sidewalls of the trenches, and gate electrodes 109 formed inside the trenches and made of polysilicon doped to a high concentration with n-type or p-type impurities. Trench MOSFETs do not exhibit JFET resistance, and therefore the more the cell pitch is reduced, the more channel resistance decreases and the more the overall ON-resistance decreases. Thus, trench MOSFETs are currently being actively developed as the next-generation successor to planar MOSFETs. Currently, various approaches are being used to develop technologies for forming trenches, technologies for forming high-quality gate oxide films on the sidewalls of trenches, and technologies for reducing the strength of electric fields applied to gate oxide films due to electric field concentration at the bottoms of trenches.

Next, a method of manufacturing such a trench MOSFET will be described with reference to FIG. 4. First, an n-type semiconductor substrate 102, an n-type drift layer 103 epitaxially grown on the n-type semiconductor substrate 102, and a p-type base layer 104 epitaxially grown on the n-type drift layer 103 are sequentially formed. Next, phosphorus (P), nitrogen (N), and arsenic (As) are selectively ion-implanted as n-type ion species and aluminum (Al) and boron (B) are selectively ion-implanted as p-type ion species, and high temperature annealing is performed at approximately 1600° C. to respectively form n-type source regions 105 and a p-type base contact region 106. Then, trenches 107 are formed using a process such as reactive ion etching (RIE). Next, gate oxide films 108 arranged on the sidewalls of the trenches 107, gate electrodes 109 made of high concentration n-type or p-type polycrystalline silicon, and interlayer insulating films 110 that insulate the gate and source are sequentially formed. Finally, a rear surface drain ohmic contact electrode 101, an ohmic contact for the n-type source regions 105 and the p-type base contact region 106, and a source electrode 111 are formed, thereby completing the device.

MOSFETs that use a silicon carbide semiconductor are switched OFF by applying 0V to the source electrode, applying 0V or a negative bias to the gate electrode, and applying a positive rated voltage (+600V for a 600V rating or +1200V for a 1200V rating) to the drain electrode. Here, although planar MOSFETs exhibit a sufficiently low leakage current I_{DSS} that is typically less than or equal to 2×10⁻⁶ A/cm², trench MOSFETs made of a silicon carbide semiconductor using the method of manufacturing described above exhibit a large leakage current I_{DSS} on the order of 10⁻³ A/cm² to 10⁻¹ A/cm² and thus exhibit non-negligibly large power loss in the OFF state.

Various methods have been proposed for reducing leakage current in trench MOSFETs. For example, one proposed technology involves forming a second electrode contacting a first region of a second conductivity type at a first bottom of a first trench and also contacting a region of a first conductivity type and a second region of the second conductivity type at a first sidewall of the first trench (see Patent Document 1, for example). Another proposed technology involves forming a p⁺ body contact region and an n⁺ source region separated from one another in the surface layer of a p-type base layer and then forming a second trench contacting the n⁺ source region and reaching an n⁻ drift layer (see Patent Document 2, for example).

Various methods of using laser beam irradiation for annealing have also been proposed. For example, one proposed technology involves forming a laser-absorbing film on the surface of an ion implantation layer formed on a substrate, heating the assembly to 1600° C. or greater, and then laser annealing (see Patent Document 3, for example). Another proposed technology involves implanting ions in another principal surface of a semiconductor substrate and then performing laser annealing-based activation annealing (see Patent Document 4, for example).

### RELATED ART DOCUMENTS

### Patent Documents

Patent Document 1: Japanese Patent Application Laid-Open Publication No. 2015-76592
Patent Document 2: Japanese Patent Application Laid-Open Publication No. 2014-33223
Patent Document 3: Japanese Patent Application Laid-Open Publication No. 2014-146757
Patent Document 4: Japanese Patent Application Laid-Open Publication No. 2007-243080

### SUMMARY OF THE INVENTION

As described above, trench MOSFETs tend to exhibit problematically large leakage currents. FIG. 5 is an emission image of a silicon carbide trench MOSFET chip with high leakage current. The emission image in FIG. 5 was taken when the drain-source voltage V_{DSS} was 600V and the leakage current I_{DSS} was 3×10⁻² A/cm². Emission images are captured with a photoemission microscope that can detect small amounts of light emitted when a semiconductor device such as a SiC device operates abnormally. Moreover, FIG. 6 is an etch pit image of the substrate surface of the silicon carbide trench MOSFET chip with high leakage current. The etch pit image in FIG. 6 was captured by removing all the layers on the silicon carbide substrate to expose the surface of the silicon carbide substrate after capturing the emission image, etching with molten KOH (potassium hydroxide), and then imaging the resulting etch pits (corrosion holes in the surface).

The etch pits correspond to threading dislocations such as screw dislocations and edge dislocations. When working with hexagonal crystal structures in 4H or 6H silicon carbide substrates or the like, these threading dislocations are known to occur along the c-axis (the <0001> direction) of the hexagonal lattice. For example, the screw dislocation indicated by the reference character a in FIG. 4 extends from the front surface of the p-type base layer 104 to the rear surface of the n-type semiconductor substrate 102. In the Miller index notation used in the present specification, the symbol − indicates a bar to be applied to the immediately following index; that is, the symbol − is inserted before an index to indicate that that index is negative.

Overlaying the emission points from the emission image in FIG. 5 (indicated by the circles) onto FIG. 6 (indicated again by the circles) makes it clear that KOH etch pits are present near these points and that the leakage current I_{DSS} occurs near threading dislocations.

Thus, the present inventor determined that the ion-implanted ion species or point defects formed during formation of the n-type source regions 105 diffuse along screw dislocations during the high temperature annealing described above and thereby convert the regions surrounding the screw dislocations to n-type. Moreover, the screw dislocations extend from the front surface of the p-type base layer 104 to the rear surface of the n-type semiconductor substrate 102. Therefore, the screw dislocations together with the surrounding n-type regions create conductive paths between the source and the drain, resulting in an increase in the leakage current I_{DSS}.

Here, it is known that increasing the impurity concentration of the p-type base layer 104 to 1×10¹⁸/cm³ reduces the leakage current I_{DSS}. However, in the trench MOSFET having the structure described above, the impurity concentration of the p-type base layer 104 is typically a lower value on the order of 1×10¹⁷/cm³. If this impurity concentration is too high, the threshold voltage (that is, the gate voltage at which current begins to flow between the drain and the source) becomes too high.

The present invention was made to solve the problems in the conventional technologies described above and aims to provide a method of manufacturing a silicon carbide semiconductor device that makes it possible to reduce leakage current while maintaining the threshold gate voltage at an appropriate value. Accordingly, the present invention is directed to a scheme that substantially obviates one or more of the problems due to limitations and disadvantages of the related art.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a method of manufacturing a silicon carbide semiconductor device, including: layering a drift layer of a first conductivity type over an entire front surface side of a silicon carbide semiconductor substrate of the first conductivity type; layering a base layer of a second conductivity type over an entire surface of the drift layer; selectively forming a source region of the first conductivity type in a surface layer of the base layer via ion implantation of impurities of the first conductivity type; selectively forming an impurity region of the second conductivity type in the surface layer of the base layer via ion implantation of impurities of the second conductivity type; laser annealing by irradiating a surface layer of the source region and a surface layer of the impurity region with a laser such that the laser irradiation activates the respective impurities in the source region and the impurity region, but does not overheat the base layer to a temperature that would promote diffusion of ion species or point defects along screw dislocations in the base layer; forming a trench going through the source region; forming a gate electrode inside the trench with a gate oxide film interposed therebetween; forming an interlayer insulating film covering the gate electrode; forming a source electrode contacting the source region and the impurity region; and forming a drain electrode on a rear surface side of the silicon carbide semiconductor substrate.

Moreover, in one aspect of the method of manufacturing the silicon carbide semiconductor device according to the present invention as described above, in the step of laser annealing, a penetration depth of the laser may be set to be greater than or equal to implantation depths of the respective impurities implanted via the ion implantations in the respective steps of forming the source region and the impurity region.

Furthermore, in one aspect of the method of manufacturing the silicon carbide semiconductor device according to the present invention as described above, in the step of laser annealing, the laser irradiation may be performed while the silicon carbide semiconductor substrate in which the source region and the impurity region are formed is heated and maintained at a prescribed temperature.

In the aspects of the present invention as described above, using laser annealing for the heat treatment makes it possible to apply heat to just the n-type source regions (the source region of the first conductivity type) and the p-type base contact region (the impurity region of the second conductivity type) without elevating the temperature of the p-type epitaxial base layer (the base layer of the second conductivity type). This prevents ion species or point defects from diffusing along screw dislocations in the p-type epitaxial base layer and thereby prevents the regions surrounding the screw dislocations in the p-type epitaxial base layer from being converted to n-type. Therefore, conductive paths are not formed between the source and drain. Moreover, in one aspect of the present invention, the film thickness and impurity concentration of the p-type epitaxial base layer are set to be equal to those of conventional trench MOSFETs, thereby making it possible to make the threshold gate voltage equal to that of conventional trench MOSFETs. Therefore, the semiconductor device according to the at least one aspect of the present invention makes it possible to prevent increases in leakage current while maintaining the threshold gate voltage at an appropriate value.

Furthermore, in the laser annealing, setting the laser penetration depth to be greater than or equal to the ion implantation depth makes it possible to activate the ion-implanted impurities. In addition, heating the n-type silicon carbide substrate and then performing laser annealing makes it possible to reduce the number of laser shots required for annealing, thereby making it possible to reduce the time required for annealing.

The method of manufacturing a silicon carbide semiconductor device according to the present invention makes it possible to reduce leakage current while maintaining the threshold gate voltage at an appropriate value. It is to be understood that both the foregoing general description and the following detailed description are exemplary and explanatory, and are intended to provide further explanation of the invention as claimed.

### BRIEF DESCRIPTION OF THE DRAWINGS

FIG. 1 is a cross-sectional view illustrating the structure of a silicon carbide semiconductor device according to an embodiment of the present invention.

FIG. 2 is a cross-sectional view illustrating a (first) state during manufacture of the silicon carbide semiconductor device according to the embodiment of the present invention.

FIG. 3 is a cross-sectional view illustrating a (second) state during manufacture of the silicon carbide semiconductor device according to the embodiment of the present invention.

FIG. 4 is a cross-sectional view illustrating the structure of a conventional trench MOSFET.

FIG. 5 is an emission image of a silicon carbide trench MOSFET chip with high leakage current.

FIG. 6 is an etch pit image of the substrate surface of the silicon carbide trench MOSFET chip with high leakage current.

### DETAILED DESCRIPTION OF EMBODIMENTS

Preferred embodiments of a method of manufacturing a silicon carbide semiconductor device according to the present invention will be described in detail below with reference to the attached drawings. In the present specification and the attached drawings, the letters “n” and “p” are used to indicate whether the majority carriers in a layer or region are electrons or holes, respectively. Moreover, the symbols+ and − are appended to the letters n and p to indicate layers or regions having a higher or lower impurity concentration, respectively, than layers or regions in which the + and − symbols are not appended. Layers and regions that are labeled with the same n and p (and + and −) notation have approximately the same impurity concentration but are not limited to having exactly the same impurity concentration. Moreover, in the following description of the embodiments and the attached drawings, the same reference characters are used to indicate components that are the same, and redundant descriptions of such components will be omitted.

### EMBODIMENTS

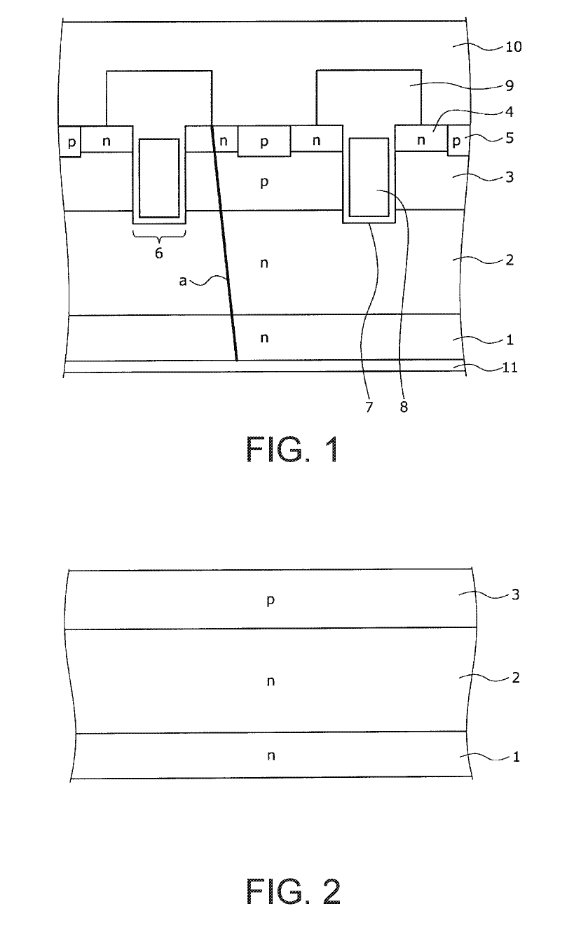

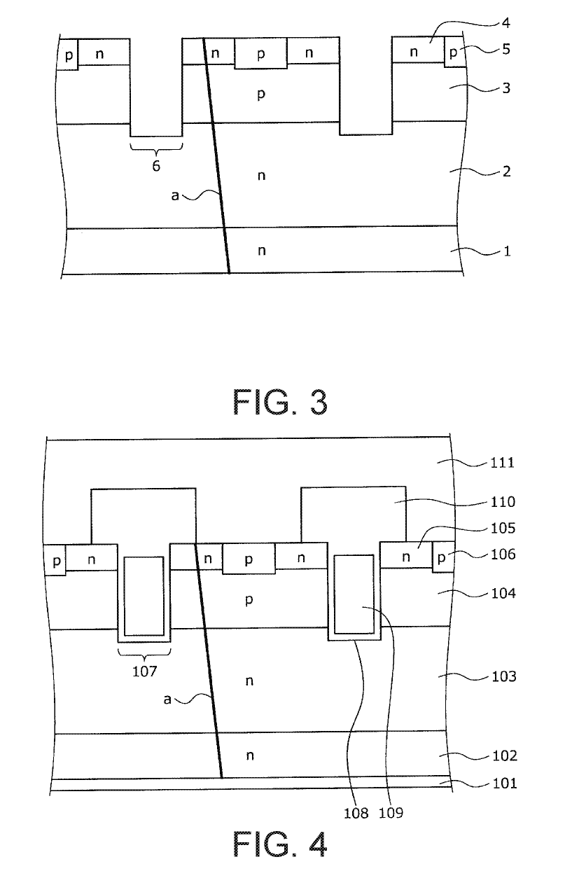

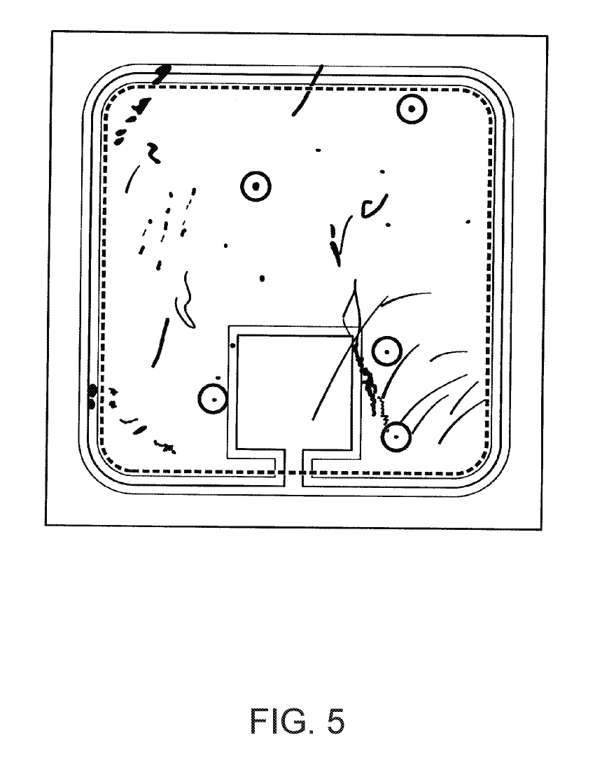

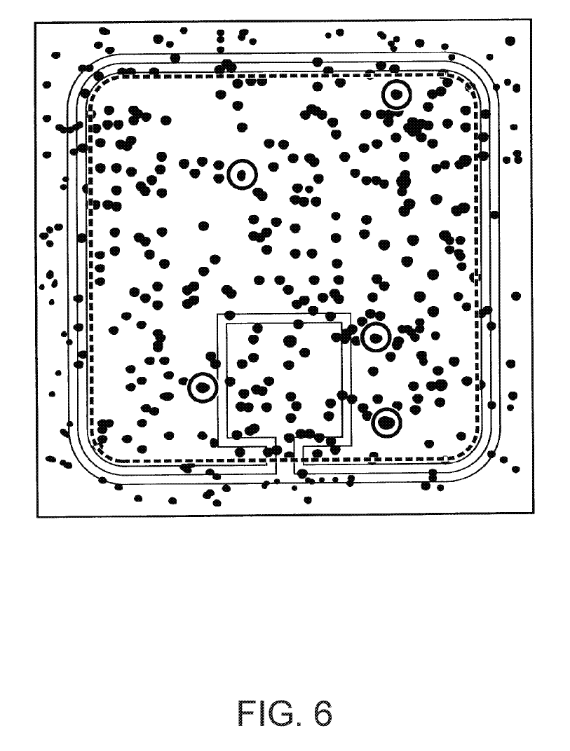

FIG. 1 is a cross-sectional view illustrating the structure of a silicon carbide semiconductor device according to an embodiment of the present invention. As illustrated in FIG. 1, in the silicon carbide semiconductor device according to the embodiment, an n-type drift layer (a drift layer of a first conductivity type) 2 is deposited onto a first principal surface (the front surface; here, the (0001) plane (Si plane), for example) of an n-type silicon carbide substrate (a silicon carbide semiconductor substrate of the first conductivity type) 1.

The n-type silicon carbide substrate 1 is a single crystal silicon carbide substrate, for example. The n-type drift layer 2 is a low impurity concentration n-type drift layer, for example, having a lower impurity concentration than the n-type silicon carbide substrate 1. A p-type epitaxial base layer (a base layer of a second conductivity type) 3 is formed on the surface of the n-type drift layer 2 on the side opposite to the n-type silicon carbide substrate 1 side. In the following description, the n-type silicon carbide substrate 1, the n-type drift layer 2, and the p-type epitaxial base layer 3 will be referred to collectively as a “silicon carbide semiconductor substrate.”

A drain electrode 11 is formed on the second principal surface of the n-type silicon carbide substrate 1 (the rear surface; that is, the rear surface of the silicon carbide semiconductor substrate).

N-type source regions (source regions of the first conductivity type) 4 and a p-type base contact region (an impurity region of the second conductivity type) 5 are selectively formed in the surface of the p-type epitaxial base layer 3 on the side opposite to the n-type silicon carbide substrate 1 side (that is, on the first principal surface side of the silicon carbide semiconductor substrate).

Trench structures are formed in the first principal surface side (the p-type epitaxial base layer 3 side) of the silicon carbide semiconductor substrate. More specifically, trenches 6 are formed, and the trenches 6 go from the surfaces of the n-type source regions 4 on the side opposite to the n-type silicon carbide substrate 1 side (that is, on the first principal surface side of the silicon carbide semiconductor substrate) through the p-type epitaxial base layer 3 and reach the n-type drift layer 2. A gate oxide film 7 is formed along the inner walls of each trench 6 (that is, on the bottom and the sidewalls of the trench 6), and a gate electrode 8, made of high impurity-doped polysilicon, is formed on the inner side of the gate oxide film 7 inside each trench 6. An interlayer insulating film 9 is formed covering the gate electrode 8. The gate oxide film 7 insulates the gate electrode 8 from the n-type drift layer 2 and the p-type epitaxial base layer 3. A portion of the gate electrode 8 may protrude from the top of the trench 6 (that is, the side on which the interlayer insulating film 9 is formed) towards a source electrode 10 side. Moreover, the n-type source regions 4 and the p-type base contact region 5 contact the source electrode 10.

Although FIG. 1 only depicts two trench-MOS structures, more of these trench-MOS gate (metal-oxide-semiconductor insulated gate) structures may be arranged in parallel.

As described above, it has been realized that if high temperature annealing were performed, the ion-implanted ion species or point defects formed during formation of the n-type source regions 4 would diffuse along screw dislocations and thereby convert the regions surrounding the screw dislocations to n-type. Here, a screw dislocation “a” extends from the front surface of the p-type epitaxial base layer 3 to the rear surface of the n-type semiconductor substrate 1, which could potentially form conductive paths between the source and the drain and result in an increase in leakage current.

The present inventor considers that these ion species or point defects would likely diffuse in this manner if annealing were performed at a high temperature of approximately 1600° C., for example. It has been reported that in silicon carbide semiconductors, using an excimer laser to increase the temperature of the substrate to 500° C. to 700° C. makes it possible to effectively activate ion-implanted impurities (see Reference Document 1, for example).

(Reference Document 1) Yasunori Tanaka et al., “Electrical activation of the ion-implanted phosphorus in 4H-SiC by excimer laser annealing,” Journal of Applied Physics, Volume 93, No. 10 (2003), pp. 5934-5936

In the silicon carbide semiconductor device according to the present embodiment, the n-type source regions 4 and the p-type base contact region 5 are annealed using laser annealing in which laser irradiation is used to perform the heat treatment. This laser annealing not only makes it possible to anneal at a substrate temperature of 500° C. to 700° C. but also makes it possible to apply heat locally to a prescribed depth from the substrate surface.

The laser annealing of the present embodiment is performed such that heat is only applied to the n-type source regions 4 and the p-type base contact region 5, and such that excess heat is not applied to the p-type epitaxial base layer 3 arranged further downwards (towards the silicon carbide semiconductor substrate side) than the n-type source regions 4 and the p-type base contact region 5. This prevents ion species or point defects from diffusing along screw dislocations in the p-type epitaxial base layer 3 and thereby prevents the regions surrounding the screw dislocations in the p-type epitaxial base layer 3 from being converted to n-type. Therefore, in the silicon carbide semiconductor device according to the present embodiment, conductive paths are not formed between the source and the drain.

(Method of Manufacturing Silicon Carbide Semiconductor Device of Embodiment)

Next, a method of manufacturing the silicon carbide semiconductor device according to an embodiment of the present invention will be described. FIGS. 2 and 3 are cross-sectional views schematically illustrating states during manufacture of the silicon carbide semiconductor device according to the embodiment.

First, the n-type silicon carbide substrate 1 made of n-type silicon carbide is prepared. Then, the n-type drift layer 2 made of silicon carbide is epitaxially grown to a thickness of approximately 30 μm, for example, on the first principal surface of the n-type silicon carbide substrate 1 while doping with n-type impurities such as nitrogen atoms. The epitaxial growth parameters for forming the n-type drift layer 2 may be set such that the resulting impurity concentration of the n-type drift layer 2 is approximately 3×10¹⁵/cm³, for example.

Next, the p-type epitaxial base layer 3 is epitaxially grown to a thickness of approximately 1 μm to 2 μm, for example, on the surface of the n-type drift layer 2 while doping with p-type impurities such as aluminum atoms. The steps thus far form the silicon carbide semiconductor substrate in which the n-type drift layer 2 and the p-type epitaxial base layer 3 are layered onto the n-type silicon carbide substrate 1. The epitaxial growth parameters for forming the p-type epitaxial base layer 3 may be set such that the resulting impurity concentration of the p-type epitaxial base layer 3 is approximately 1×10¹⁷/cm³ to 4×10¹⁷/cm³, for example. FIG. 2 illustrates the state of the device up to this point.

Next, a mask (not illustrated in the figures) having the desired openings and made of an oxide film, for example, is formed on the surface of the p-type epitaxial base layer 3 using photolithography technology, and using this oxide film as a mask, n-type impurities such as nitrogen are ion-implanted into the surface of the p-type epitaxial base layer 3. In this way, the n-type source regions 4 are formed to a depth of approximately 0.5 μm, for example, in portions of the surface region of the p-type epitaxial base layer 3. The dose used during the ion implantation for forming the n-type source regions 4 may be set such that the resulting impurity concentration is approximately 1×10¹⁷/cm³, for example. Then, the mask used during the ion implantation for forming the n-type source regions 4 is removed.

Next, a mask (not illustrated in the figures) having the desired openings and made of an oxide film, for example, is formed on the surface of the p-type epitaxial base layer 3 using photolithography technology, and using this oxide film as a mask, p-type impurities such as aluminum are ion-implanted into the surface of the p-type epitaxial base layer 3. In this way, the p-type base contact region 5 is formed to a depth of approximately 0.5 μm, for example, in a portion of the surface region of the p-type epitaxial base layer 3. The dose used during the ion implantation for forming the p-type base contact region 5 may be set such that the resulting impurity concentration is greater than that of the p-type epitaxial base layer 3, for example. Then, the mask used during the ion implantation for forming the p-type base contact region 5 is removed.

Next, using photolithography technology, a mask (not illustrated in the figures) having the desired openings and made of an oxide film, for example, is formed on the surfaces of the n-type source regions 4 and the p-type base contact region 5. Then, using this oxide film as a mask, dry etching or the like is performed to form the trenches 6 going through the p-type epitaxial base layer 3 and reaching the n-type drift layer 2. Next, the mask used to form the trenches 6 is removed. FIG. 3 illustrates the state of the device up to this point. Note that the order in which the n-type source regions 4 and the p-type base contact region 5 are formed may be reversed. That is, the n-type source regions 4 may be formed after forming the p-type base contact region 5.

Next, a heat treatment (annealing) is performed to activate the n-type source regions 4 and the p-type base contact region 5. This heat treatment is laser annealing in which the surface layer of the n-type source regions 4 and the surface layer of the p-type base contact region 5 are irradiated with a laser. In this laser annealing, the penetration depth of the laser is set to be greater than or equal to the implantation depth of the ion-implanted ions in order to ensure that all of the ion-implanted ions are activated. For example, when the n-type source regions 4 and the p-type base contact region 5 are formed to a depth of 0.5 μm, the laser penetration depth is set to 0.5 μm. The heat treatment may be performed one time as described above to activate all of the ion-implanted regions at once, or the heat treatment may be performed after each ion implantation.

Next, the laser annealing step of the embodiment of the present invention will be described in more detail. In the embodiment, a xenon chloride (XeCl) laser with a wavelength of 308 nm and a laser penetration depth of 2.6 μm, for example, is used for the laser. Moreover, in the laser annealing, it is preferable that the laser irradiation energy be set to 1.0 J/cm², that the pulse width be set to 20 ns, and that 600 to 3000 shots be performed.

At 2000 shots or fewer, the temperature of the p-type epitaxial base layer 3 does not increase and thus leakage current I_{DSS} does not increase, but at greater than 2000 shots, I_{DSS} begins to increase due to an increase in the temperature of the p-type epitaxial base layer 3. Meanwhile, at least 1500 shots are required to elevate the temperatures of the n-type source regions 4 and the p-type base contact region 5 enough to achieve activation. Therefore, it is preferable that 1500 to 2000 shots be performed during the laser annealing.

Moreover, when laser annealing is to be performed, heat may be applied to the silicon carbide semiconductor substrate 1 in which the n-type source regions 4 and the p-type base contact region 5 are formed in order to raise the substrate temperature during the laser annealing. In this case, the laser irradiation condition is adjusted. For example, if the silicon carbide semiconductor substrate 1 is heated to 500° C., it is easier to elevate the temperatures of the p-type epitaxial base layer 3, the n-type source regions 4, and the p-type base contact region 5, and therefore, the leakage current I_{DSS} begins to increase at 2000 shots or more. On the other hand, at least 500 shots are required to achieve activation under this condition. Therefore, when the silicon carbide semiconductor substrate 1 is heated to 500° C., it is preferable that 500 to 1000 shots be performed during the laser annealing.

Next, the gate oxide film 7 is formed along the surfaces of the n-type source regions 4 and the p-type base contact region 5 and along the bottoms and sidewalls of the trenches 6. The gate oxide film 7 may be formed using thermal oxidation in which a heat treatment is performed in an oxygen atmosphere at a temperature of approximately 1200° C. Alternatively, the gate oxide film 7 may be formed using a deposition method based on a chemical reaction such as high temperature oxidation (HTO).

Next, a polycrystalline silicon layer doped with phosphorus atoms, for example, is formed on the gate oxide film 7. This polycrystalline silicon layer is formed filling the interiors of the trenches 6. The polycrystalline silicon layer is then patterned and left remaining only inside the trenches 6 to form the gate electrodes 8. A portion of each gate electrode 8 may protrude from the top of the respective trenches 6 (that is, the side on which the interlayer insulating film 9 is formed) towards the source electrode 10 side.

Next, a phosphosilicate glass film with a thickness of approximately 1 μm, for example, is formed covering the gate oxide film 7 and the gate electrodes 8 to form the interlayer insulating film 9. The interlayer insulating film 9 and the gate oxide film 7 are then selectively removed using patterning to form contact holes, thereby exposing the n-type source regions 4 and the p-type base contact region 5. Then, a heat treatment (reflow) is performed to planarize the interlayer insulating film 9.

Next, a film such as an aluminum-silicon (Al—Si) alloy film that becomes the source electrode 10 is formed inside the contact holes and on the interlayer insulating film 9. This conductive film is then selectively removed to leave the source electrode 10 in designated areas including the inside of the contact holes, for example.

Next, the drain electrode 11 made of a nickel (Ni) film, for example, is formed on the second principal surface of the n-type silicon carbide substrate 1. Then, a heat treatment is performed at a temperature of approximately 1000° C., for example, to form an ohmic contact between the n-type silicon carbide substrate 1 and the drain electrode 11.

Next, an aluminum film with a thickness of approximately 5 μm is formed covering the source electrode 10 and the interlayer insulating film 9 using a sputtering method, for example. Then, the aluminum film is selectively removed but left covering the entire active portion of the device, thereby forming a source electrode pad (not illustrated in the figures).

Next, titanium (Ti), nickel, and gold (Au), for example, are sequentially layered onto the surface of the drain electrode 11 to form a drain electrode pad (not illustrated in the figures). This completes the silicon carbide semiconductor device illustrated in FIG. 1.

When the acceptable leakage current I_{DSS} for a square chip 3 mm in size is set to 100 nA or less, the yield rate of the silicon carbide semiconductor devices that were manufactured according to the embodiment of the present invention, meeting this I_{DSS} condition, was improved to approximately 99% from the yield rate of only approximately 1% typically seen in conventional technologies. Moreover, in the silicon carbide semiconductor devices that were manufactured according to the embodiment of the present invention, the threshold voltage was 5V to 6V, the avalanche breakdown voltage (withstand voltage) for the 1200V class devices was sufficiently high at 1500V to 1600V, and there was no evidence of punchthrough.

In the embodiments as described above, using laser annealing for the heat treatment makes it possible to apply heat to just the n-type source regions and the p-type base contact region without elevating the temperature of the p-type epitaxial base layer. This prevents ion species or point defects from diffusing along screw dislocations in the p-type epitaxial base layer and thereby prevents the regions surrounding the screw dislocations in the p-type epitaxial base layer from being converted to n-type. Therefore, conductive paths are not formed between the source and drain. Moreover, in some of the embodiments, because the film thickness of the p-type epitaxial base layer is approximately 1 μm to 2 μm and the impurity concentration of the p-type epitaxial base layer is approximately 1×10¹⁷/cm³ to 4×10¹⁷/cm³, the threshold gate voltage is equal to that of conventional trench MOSFETs. Therefore, the semiconductor device according to the embodiments of the present invention makes it possible to prevent increases in leakage current while maintaining the threshold gate voltage at an appropriate value.

Furthermore, in the laser annealing, setting the laser penetration depth to be greater than or equal to the ion implantation depth makes it possible to activate the ion-implanted impurities. In addition, heating the n-type silicon carbide substrate while performing the laser annealing makes it possible to reduce the number of laser shots required for annealing, thereby making it possible to reduce the time required for annealing.

Various modifications can be made to the present invention as described above without departing from the spirit of the present invention. For example, the dimensions, impurity concentrations, and the like used for each portion of the device in the embodiment described above can be configured as necessary to satisfy design requirements or the like. Moreover, although in the embodiment of the present invention as described above the first conductivity type was n-type and the second conductivity type was p-type, the present invention still exhibits all of the same advantageous effects if the first conductivity type is p-type and the second conductivity type is n-type.

### INDUSTRIAL APPLICABILITY

The method of manufacturing a silicon carbide semiconductor device according to the present invention as described above is suitable for application to methods of manufacturing silicon carbide semiconductor devices having at least two or more p-n junctions, such as trench-gate MOSFETs, insulated-gate bipolar transistors (IGBTs), junction gate field-effect transistors (JFETs), bipolar junction transistors (BJTs), gate turn-off thyristors (GTOs), and thyristors. The present invention is particularly well-suited to application to methods of manufacturing silicon carbide MOS power semiconductor devices.

It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A method of manufacturing a silicon carbide semiconductor device, comprising:
layering a drift layer of a first conductivity type over an entire front surface side of a silicon carbide semiconductor substrate of the first conductivity type;
layering a base layer of a second conductivity type over an entire surface of the drift layer;
selectively forming a source region of the first conductivity type in a surface layer of the base layer via ion implantation of impurities of the first conductivity type;
selectively forming an impurity region of the second conductivity type in the surface layer of the base layer via ion implantation of impurities of the second conductivity type;
laser annealing by irradiating a surface layer of the source region and a surface layer of the impurity region with a laser such that the laser irradiation activates the respective impurities in the source region and the impurity region, but does not overheat the base layer to a temperature that would promote diffusion of ion species or point defects along screw dislocations in the base layer;
forming a trench going through the source region;
forming a gate electrode inside the trench with a gate oxide film interposed therebetween;
forming an interlayer insulating film covering the gate electrode;
forming a source electrode contacting the source region and the impurity region; and
forming a drain electrode on a rear surface side of the silicon carbide semiconductor substrate.

2. The method of manufacturing the silicon carbide semiconductor device according to claim 1, wherein in the step of laser annealing, a penetration depth of the laser is set to be greater than or equal to implantation depths of the respective impurities implanted via said ion implantations in the respective steps of forming the source region and the impurity region.

3. The method of manufacturing the silicon carbide semiconductor device according to claim 1, wherein in the step of laser annealing, the laser irradiation is performed while the silicon carbide semiconductor substrate in which the source region and the impurity region are formed is heated and maintained at a prescribed temperature.

4. The method of manufacturing the silicon carbide semiconductor device according to claim 2, wherein in the step of laser annealing, the laser irradiation is performed while the silicon carbide semiconductor substrate in which the source region and the impurity region are formed is heated and maintained at a prescribed temperature.
